(19) United States
(12) Patent Application Publication
(10) Pub. No.: US 2004/0039982 A1
(43) Pub. Date: Feb. 26, 2004

(54) Dot code and dot code reader

(76) Inventors: Hideki Chujo, Kyoto-shi (JP); Manabu Ohshima, Kyoto-shi (JP)

Correspondence Address: FOLEY AND LARDNER, SUITE 500, 3000 K STREET NW, WASHINGTON, DC, 20007, US

(21) Appl. No.: 10/363,915

(22) PCT Filed: Sep. 7, 2001
(86) PCT No.: PCT/JP01/07761

(30) Foreign Application Priority Data
Sep. 12, 2000 (JP) 2000-276167

(51) Int. Cl. H03M 13/00

(52) U.S. Cl. 714/758

(57) ABSTRACT

The present invention relates to a dot code and a reader which is adapted to prevent the codes on the upper and lower lines from overlapping with each other and to be positively read out. A two-dimensional code is realized which can be read out positively. A printing section, when printing a two-dimensional code, prints dots on every other line. Dots are printed on every column. However, on the adjacent columns, dots are printed in a manner deviated in phase. With this, in the case of detecting a dot concentration in each direction of line and determining a presence or absence of a code, the waveform representing a color tone deviates in phase line by line, thus making possible to positively recognize a change in the lines.

### TECHNICAL FIELD

The present invention relates to a dot code and a dot code reader, and more particularly to a dot code and a dot code reader that the codes on the upper and lower lines are prevented from overlapping with each other to be positively read out.

### BACKGROUND ART

Recently, there is a tendency toward utilizing the sound data having great data amount in the two-dimensional code. The two-dimensional code is, for example, to be printed on a medium, such as a paper, by a dot-printing ink-jet printer or dot-impact printer.

Usually, the two-dimensional code is configured by a gathering of predetermined-sized blocks, as shown in FIGS. 1 and 2.

In the case of the FIG. 1 example, one code (1 bit) is expressed by vertically 4×horizontally 4 dots (totally 16 dots). In the case of the FIG. 2 example, one code is expressed by vertically 3×horizontally 3 dots (totally 9 dots). Thus, by a presence or absence of a block (code) in each position, a predetermined code is expressed. Accordingly, by previously printing such a two-dimensional code on a printing matter or the like, various pieces of information can be assigned to that printing matter.

In the meanwhile, for increasing information amount by a constant printing area, it is the best way to decrease the number of dots configuring one code. Namely, as shown in FIG. 3, in the case of expressing one code by 1 dot, information amount becomes the greatest.

However, in case dots are printed in the upper, lower, left and right adjacent positions at a maximum resolution pitch P of a printer as is shown in FIG. 4, the dot in the adjacent region is printed outer even in the case dot print is not made in the center. Accordingly, when the two-dimensional code is read out, there is a fear to read out by mistake that there exist a dot in the center region despite actually it is not in existence.

Consequently, in the case of expressing one code by 1 dot, it is a general practice to carry out printing with a print density coarser than the maximum resolution pitch P of a printer as shown in FIG. 5, in order to prevent an overlap of dots.

In the case of FIG. 5 example, when a row or column pitch is taken P in both directions of row and column directions, the dots are printed at an interval of 2P. Incidentally, the dot has a diameter given a value somewhat greater than the maximum resolution pitch P. The dot is not in a perfect circle but nearly circular. Dot diameter means a diameter of a circle thereof.

In the meanwhile, conventionally, in the case of expressing one code by 1 dot, even when printing with a print density coarser than the maximum resolution pitch P of printer, dots are arranged in a square form at an even pitch.

As a result, where a printer prints a dot code to a medium (paper), when considering a deviation in a transport direction of the medium, printing position somewhat deviates from a target printing position, resulting in a problem of difficulty in distinguishing the lines.

FIG. 6 is a figure explaining a dot code example in the case that printing position somewhat deviates toward a medium-transport direction. As shown in the figure, on line L₂ and line L₃, dots are printed deviated from a target printing position (position shown by the hatched square, in the figure) to which the printer is naturally to print. Namely, dots are printed outer toward a direction of line L₃ (lower, in the figure) on the line L₂ and toward a direction of line L₂ (upper, in the figure) on the line L₃, respectively.

In the dot code shown in FIG. 6, when considering a color-tone waveform of a signal in the case that the respective printed dots are read out along line L₂ and line L₃, the color-tone waveform of the signals on line L₂ and line L₃ are nearly the same in phase, as shown respectively in FIG. 6A or FIG. 6B, thus being overlapped at the upper and lower.

As a result, distinction is difficult between the codes on the upper and lower lines, resulting in a fear to reduce the recognition ratio of dot code.

### DISCLOSURE OF THE INVENTION

The present invention, made in view of such a circumstance, is to realize a dot code suppressing the codes on the upper and lower lines from overlapping with each other to be positively read out.

A dot code of the invention is characterized in that: in rows on which the dots are arranged, which rows are adjacent to each other, arrangement is in a manner the dots deviate in phase.

In this dot code, in mutually adjacent rows on which the dots are arranged, arrangement is in a manner the dots deviate in phase. This can realize a dot code suppressing the codes on the upper and lower lines from overlapping with each other to be positively read out.

The dot herein, in a row direction or both directions of row and column directions, has a value somewhat greater than a maximum resolution pitch of a printer, such as an ink-jet printer (trademark) or impact printer. Also, the dot is not a perfect circle but almost circular. The dot diameter means a diameter of a circle thereof.

Phase means a deviation in time, space or position of a waveform representative of a dot color tone.

A dot code printer of the invention is characterized by comprising: converting means for converting input data into a dot code; and printing means for printing, to the medium, the dot code converted by the converting means; the printing means arranging the dots in a manner the dots deviate in phase, in rows on which the dots are arranged, which rows are adjacent to each other.

In the dot code printer of the invention, input data is converted into a dot code and a converted dot code is printed to a medium. The printing means arranges dots in a manner the dots deviate in phase, in rows on which the dots are arranged, which rows are adjacent to each other.

A dot code printing method of the invention is characterized by comprising: a converting step of converting input data into a dot code; and a printing step of printing, to the medium, the dot code converted by the process of the converting step; in the printing step the dots being arranged in a manner the dots deviate in phase, in rows on which the dots are arranged, which rows are adjacent to each other.

In the dot code printing method of the invention, input data is converted into a dot code and a converted dot code is printed to a medium. In the printing step dots are arranged in a manner the dots deviate in phase, in rows on which the dots are arranged, which rows are adjacent to each other.

A dot code reader of the invention is characterized by comprising: reading means for reading out the dot code configured by the dots in plurality; binary means for making binary data read out by the reading means; operating means for operating an exclusive OR on adjacent pixels in a column direction of data made binary by the binary means; and determining means for determining a pause in a row of the dots on the basis of an operation result by the operating means.

In the dot code reader of the invention, dot code configured by the dots in plurality is read out and the read out data is made binary. On the basis of an exclusive OR operation result on the adjacent pixels in the column direction of the binary data, determined is a pause in a row of the dots. Due to this, it is possible to positively recognize a change in the upper and lower lines.

The reading means radiates light to a card on which a two-dimensional code is printed. A reading device, such as of a CCD imaging device, images the surface of the card printed with the two-dimensional code, thereby reading out the two-dimensional code.

The binary means make binary the image signal read out by the reading means, in synchronism with a synchronization signal synchronous with the operation of reading out.

The operating means operates an exclusive OR with the pixel adjacent upper in the column direction, in each pixel of the data made binary by the binary means.

The determining means determines, as a pause on the row, a row including a pixel that the operation value the operating means operated is 1.

A dot code reading method of the invention is characterized by comprising: a reading step of reading out the dot code configured by the dots in plurality; a binary step of making binary data read out by the reading step; an operating step of operating an exclusive OR on adjacent pixels in a column direction of data made binary by the binary step; and a determining step of determining a pause in a row of the dots on the basis of an operation result by the operating step.

In the dot code reading method of the invention, dot code configured by the dots in plurality is read out and the read out data is made binary. On the basis of an exclusive OR operation result on the adjacent pixels in the column direction of the binary data, determined is a pause in a row of the dots. Due to this, it is possible to positively recognize a change in the upper and lower lines.

### BRIEF DESCRIPTION OF THE DRAWINGS

FIG. 1 is a figure for explaining a conventional dot code.

FIG. 2 is a figure for explaining a conventional dot code in another example.

FIG. 3 is a figure for explaining a conventional dot code in still another example.

FIG. 4 is a figure for explaining a dot print density.

FIG. 5 is a figure for explaining a dot print density in another example.

FIG. 6 is a figure for explaining a deviation in dot print position.

FIG. 7 is a block diagram showing a configuration example of a printer to which the invention is applied.

FIG. 8 is a figure for explaining a print example on a card of FIG. 7.

FIG. 9 is a block diagram showing a configuration example of a card reader to which the invention is applied.

FIG. 10 is a figure showing a dot print state.

FIG. 11 is a figure showing a state of print with a phase shift.

FIG. 12 is a figure showing a state of print with a phase shift in another example.

FIG. 13 is a figure showing a color-tone waveform of a dot shown in FIG. 12.

FIG. 14 is a figure showing a state of print with a phase shift.

FIG. 15 is a figure for explaining the operation of reading out.

FIG. 16 is a figure for explaining a state the dot shown in FIG. 15 has been read out.

FIG. 17 is a figure for explaining a result of detecting a pause on the line.

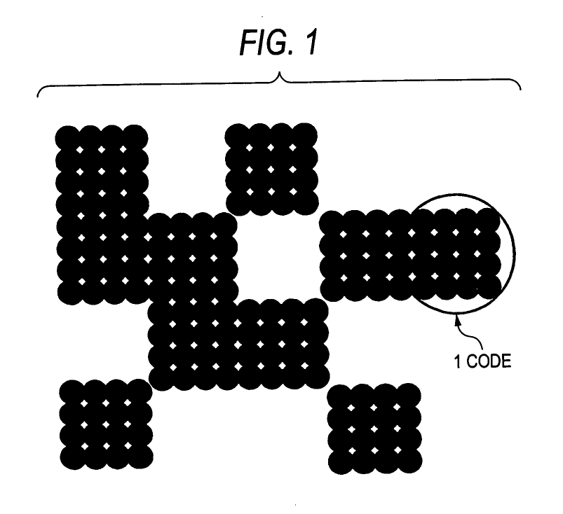

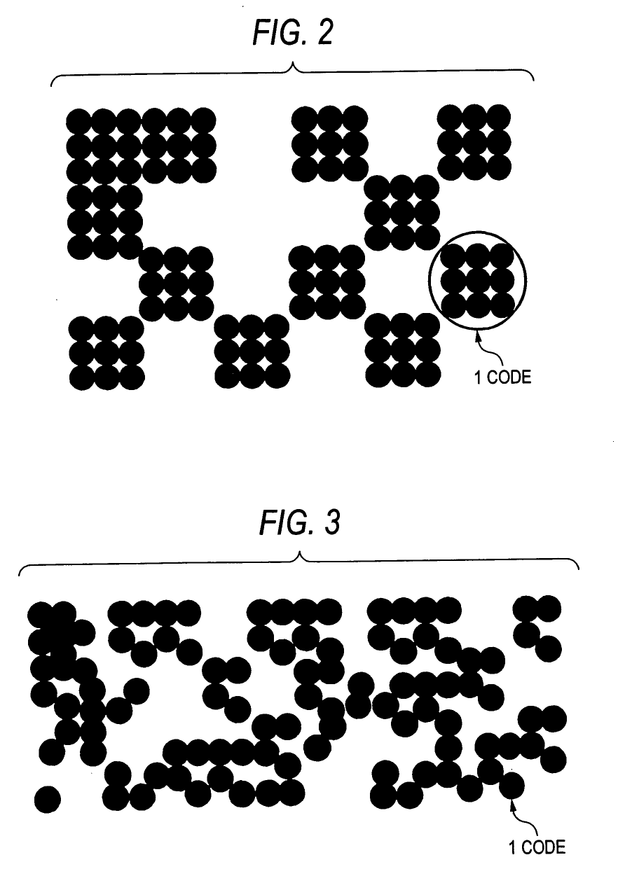

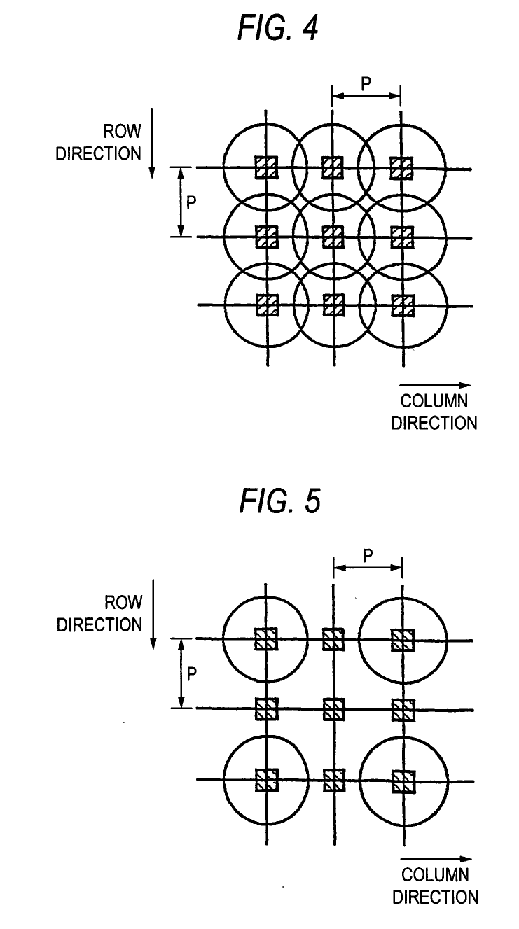

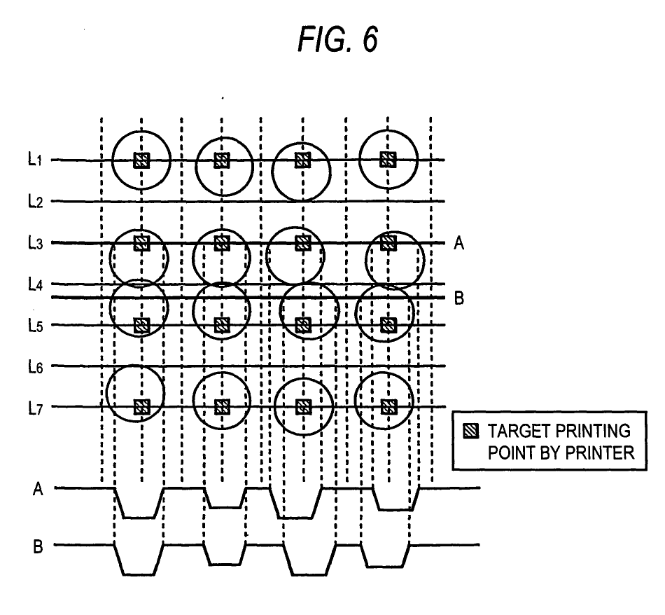

### BEST MODE FOR CARRYING OUT THE INVENTION

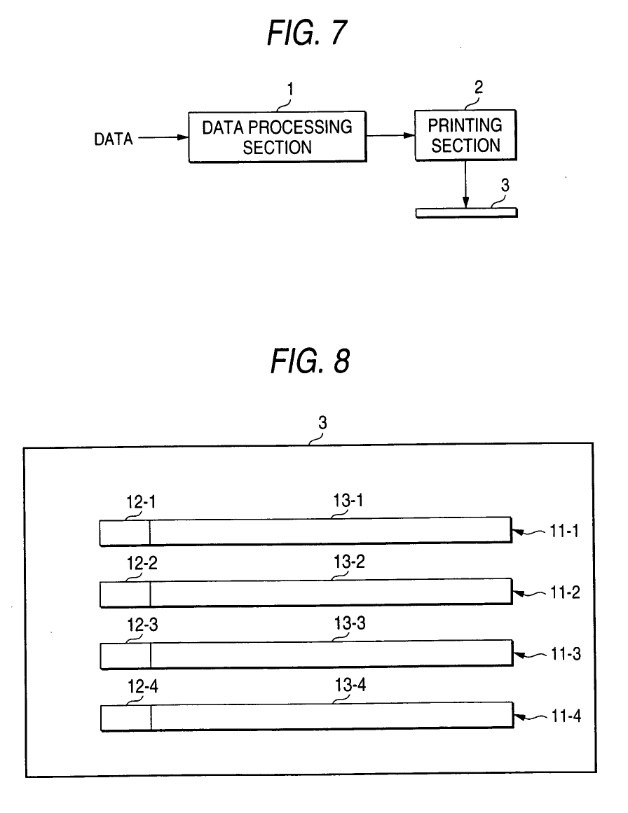

FIG. 7 shows a configuration example of one embodiment of a printer to which the present invention is applied. In this configuration example, the data corresponding to a two-dimensional code (e.g. audio data) to be printed on a card 3 is inputted to a data processing section 1. The data processing section 1 converts the input data into a two-dimensional code pattern and outputs it to a printing section 2. The printing section 2 prints a print pattern inputted from the data processing section 1 onto the card 3 structured of paper, plastic or the like.

FIG. 8 shows an example of a card 3 thus printed with a two-dimensional code. In this example, four two-dimensional codes 11-1 to 11-4 (hereinafter, in the case that there is no need to individually distinguish these two-dimensional codes 11-1 to 11-4, description is merely as two-dimensional code 11. This is true for other passages) are printed. The two-dimensional code 11-1 is divided with a header section 12-1 and a data section 13-1. The header section 12-1 records a kind of the data recorded in the data section 13-1, a version, and other pieces of information. In the case of the example of FIG. 8, the data section 13-1 records audio data. This is true for the two-dimensional codes 11-2 to 11-4.

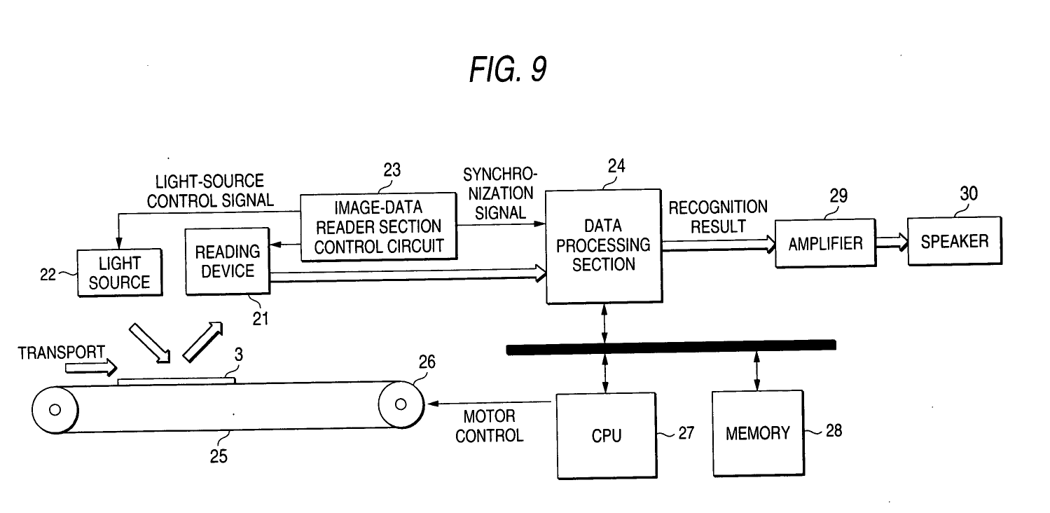

FIG. 9 shows a structural example of a reader for reading a card 3 printed with a two-dimensional code 11. The card 3 is rested on a belt 25, in a position the surface printed with the two-dimensional code 11 directs up. Since a motor 26 drives the belt 25, the card 3 is transported (moved) from the left direction to the right direction in the figure.

A light source 22 generates light correspondingly to a light-source control signal outputted by an image-data reader section control circuit 23 and radiates it to the card 3. For example, a reader device 21 such as a CCD imaging device is controlled by the image-data reader section control circuit 23, to image a surface of the card 3 printed with the two-dimensional code 11 and output an image signal obtained as a result of imaging thereof to a data processing section 24.

The data processing section 24 also is inputted by a synchronization signal synchronous with the operation of image reading, from the image-data reader section control circuit 23. The data processing section 24, in synchronism with the synchronization signal inputted from the image-data reader section control circuit 23, makes binary the image signal inputted from the reader device 21 and carries out a recognition process thereby generating a binary code based on a recognition result. The data processing section 24 further converts this binary code into an analog audio signal and outputs it to a speaker 30 through an amplifier 29.

A CPU 27 controls the data processing section 24 and motor 26. A memory 28 is properly stored with the data and program required for the CPU 27 to execute various processes.

Next, the operation is explained. The CPU 27, when instructed for read start from the user, controls the motor 26 and drives the belt 25. Due to this, the card 3 rested on the belt 25 is transported in the direction of from left to right in the figure.

The CPU 27 also controls the image-data reader section control circuit 23, and causes the light source 22 to generate light and radiate it to the card 3. At this time, the reader device 21 is controlled by the image-data reader section control circuit 23, to read out the two-dimensional code 11 printed on the card 3. The data processing section 24 makes binary the image signal inputted by the reader device 21 and converts it into binary data, thereafter converting it into an analog audio signal. This analog audio signal is outputted to the speaker 30 through the amplifier 29.

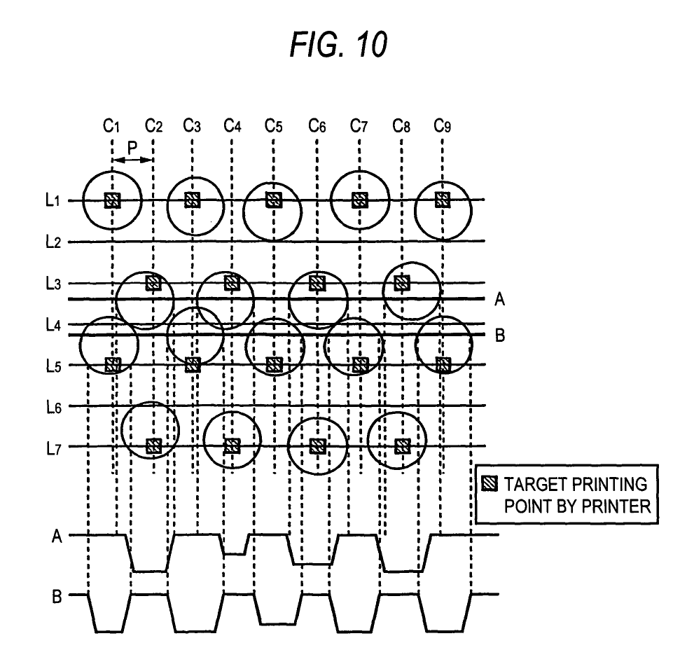

Next, explanation is made on the two-dimensional code to be printed on the card 3, with reference to FIG. 10. The print section 2, for printing on the card 3, has a maximum resolution pitch value provided P. In the case of the example of FIG. 10, dot diameter is given a value somewhat greater than the pitch value P of the maximum resolution.

In the print section 2, when a two-dimensional code is printed to the card 3, dots are printed every other line (on odd-numbered lines in the example of FIG. 10), i.e. at an interval of 2P, as shown in FIG. 10. Furthermore, dots are printed on every row. However, on the adjacent rows, dots are printed in a manner deviated in phase. In the case of the example of FIG. 10, dots are printed on the column C₁, C₃, C₅, C₇, C₉ on the line L₁, L₅, and on the column C₂, C₄, C₆, C₈ on the line L₃, L₇, respectively.

If doing so, in the case of detecting a dot concentration in each line (row) direction and determining a presence or absence of a code, the phase of a waveform representative of a shade of color deviates line by line, thus making it possible to positively recognize a change in the lines. Namely, in the case of the example of FIG. 10, the dots printed on line L₃ and line L₅ are deviated from the target print points where the printer is naturally to print and respectively printed on lines A, B. However, because the color-shade waveforms on line A and line B positively deviate in phase as shown in FIGS. 10A and 10B, it is possible to easily distinguish between the codes on the upper and lower lines. Incidentally, in FIG. 10A and FIG. 10B, the portion corresponding to the dot is taken as low level to represent the portion not corresponding to the dot as high level.

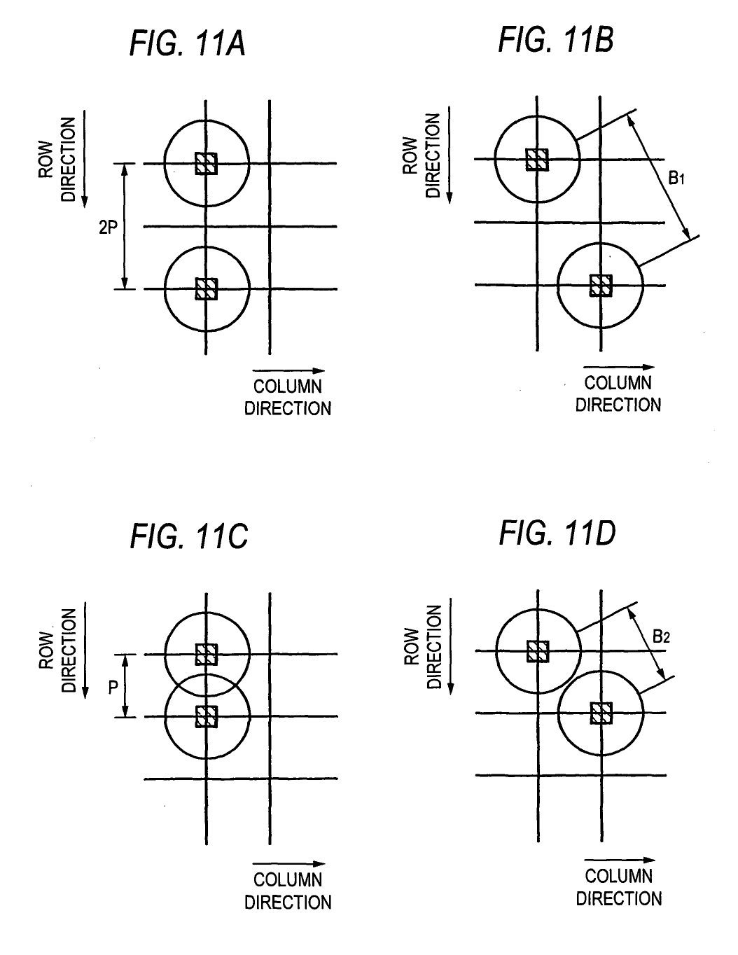

Meanwhile, as shown in FIG. 11(A), in the case the phase is not deviated, the spacing between two dots is 2P. However, if the phase is deviated, the spacing B₁ between two dots becomes longer than 2P. Similarly, as shown in FIG. 11(C), in case two dots are printed without phase deviation, the spacing is P. However, if deviating the phase, the spacing becomes a spacing B₂ longer than P. As a result, the codes on the upper and lower lines are suppressed correspondingly from overlapping with each other.

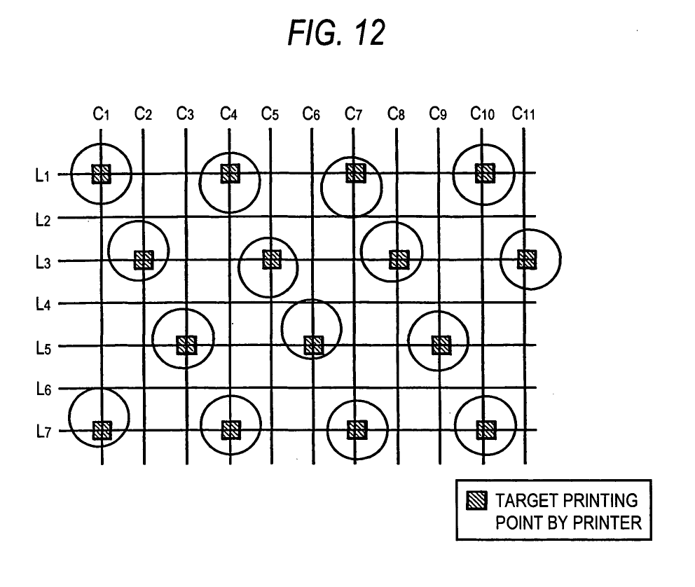

In the example of FIG. 10, the phase kind was two kinds. However, in also the case of printing with a two-dot spacing in a row direction and a one-dot spacing in a column direction as shown in FIG. 12 for example, i.e. even in case the phase kind is three kinds, the codes on the upper and lower lines can be suppressed from overlapping with each other.

In FIG. 12, dots are printed every other line (on odd-numbered lines, in the example of FIG. 12), i.e. at an interval of 2P. Furthermore, dots are printed on every column. However, on the adjacent columns, dots are printed in a manner of phase deviation. In the case of the example of FIG. 12, dots are printed on lines L₁, L₇ on the columns C₁, C₄, C₇, C₁₀, on line L₃ on the columns C₂, C₅, C₈, C₁₁, and on line L₅ on the columns C₃, C₆, C₉.

By doing so, in the case of detecting a dot concentration in line (row) direction and determining a presence or absence of a code, the phase of a waveform representative of a color shade deviates line by line, thus making it possible to positively recognize line change. Namely, in the case of the example of FIG. 12, because the dots printed on line L₁, line L₃ and line L₅ are positively deviated in phase (because the phase kind is three kinds), it is possible to easily distinguish between the codes on the upper and lower lines.

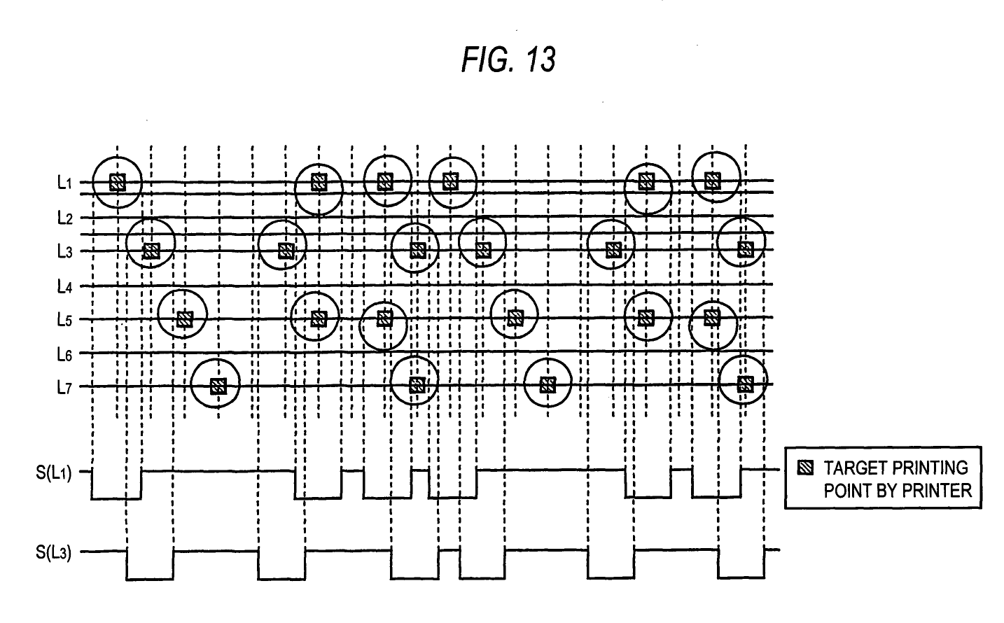

FIG. 13 represents color-shade waveforms S(L₁) and S(L₃) of the dots on the line L₁ and line L₃ printed by a printing method as shown in FIG. 12. As shown in the figure, because the phases of the color-shade waveforms on the line L₁ (S(L₁)) and the line L₃ (S(L₃)) deviate line by line, the change in the upper and lower lines can be positively recognized.

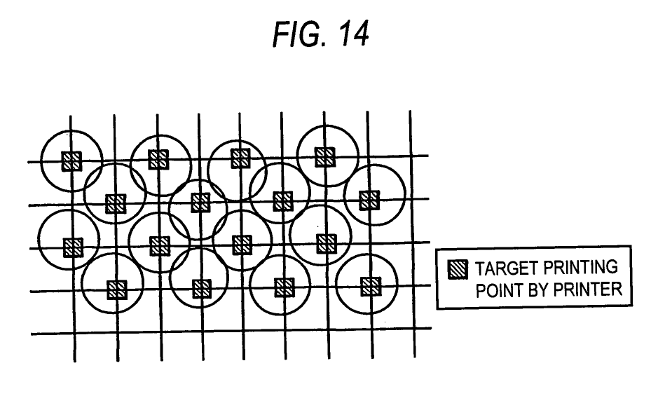

FIG. 14 represents an example in the case of printing with a one-dot spacing in the row direction and using every dot in the column direction. As shown in the figure, because of a phase deviation line by line, it is also possible to suppress the codes on the upper and lower lines from overlapping with each other. Incidentally, although dot arrangement as in FIG. 14 is possible, there is a case that dots are not printed on all the columns depending upon the data representative of the relevant dot code.

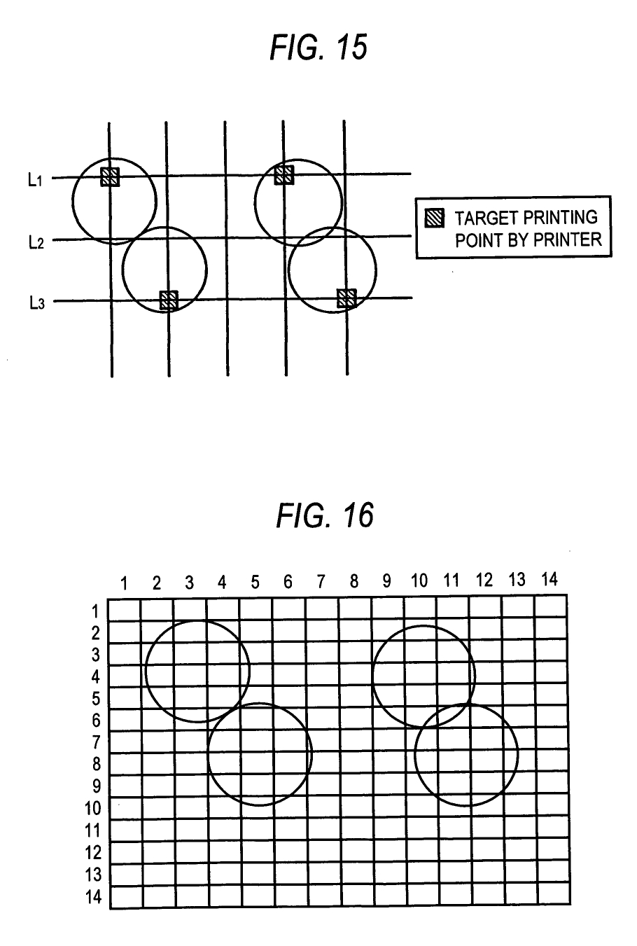

Next, with reference to FIGS. 15 to 17, explanation is made on the operation of reading out a two-dimensional code by the reader.

For example, considered is the operation for reading out a two-dimensional code as shown in FIG. 15. As shown in the figure, the dots printed on the line L₁, and the line L₃ are respectively printed with deviations in the lower direction or in the upper direction in the figure from a target print point where the printer is naturally to print.

First, the reading device 21 reads out a two-dimensional dot code as shown in FIG. 15, on the basis of control of the image-data reading section control circuit 23. Due to this, as shown in FIG. 16, dot color shade is read out and a plurality of pixel signals are outputted to the data processing section 24.

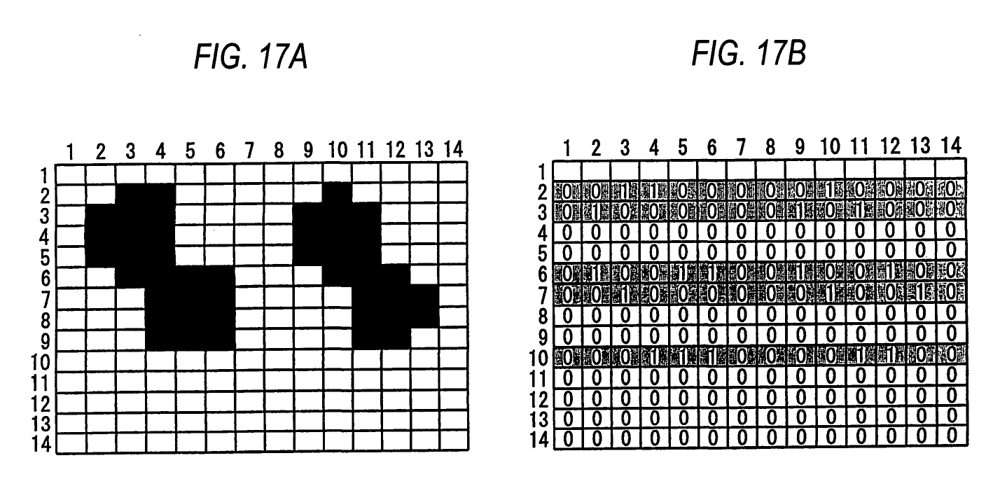

The data processing section 24 makes binary the pixel signals inputted by the reading device 21. Namely, the data processing section 24 makes binary the data-existing pixel as 1 and the data-not-existing pixel as 0, as shown in FIG. 17(A).

Then, the data processing section 24 calculates an exclusive OR with a pixel adjacent upper in a column direction, in each pixel of binary data. For example, in FIG. 17(A), an exclusive OR is calculated for the pixel on the second row and third column ((row 2, column 3)=1) with the pixel on the first row and third column ((row 1, column 3)=0). As a result, calculated is ({(row 2, column 3)=1}+{(row 1, column 3)=0})=1.

Also, for example, an exclusive OR between the pixel on the third row and third column ((row 3, column 3)=1) and the pixel on the second row and third column ((row 2, column 3)=1) is calculated as ({(row 3, column 3)=1}+{(row 2, column 3)=1})=0.

Furthermore, for example, an exclusive OR between the pixel on the seventh row and third column ((row 7, column 3)=0) and the pixel on the sixth row and third column ((row 6, column 3)=1) is calculated as ({(row 7, column 3)=0}+{(row 6, column 3)=1})=1.

Similarly, if calculating the exclusive ORs in the pixels, the result is as shown in FIG. 17(B).

Consequently, by calculating an exclusive OR on the pixels of the binary data adjacent in the column direction, it is seen that the row including a pixel in which an operation value is 1 is resultingly a change point (boundary between the dots on the upper line and the dots on the lower line). Namely, in the case of the example of FIG. 17(B), it is seen that the second, third, sixth, seventh and tenth rows are change points.

As in the above, by calculating an exclusive OR on the pixels of binary data adjacent in the column direction, it is possible to easily detect a change point of the upper and lower lines (i.e., easily distinguish between the upper and lower lines). Also, because the phase positively deviates line by line, the codes on the upper and lower lines can be suppressed from overlapping each other.

### INDUSTRIAL APPLICABILITY

According to the dot code of the present invention, the codes on the upper and lower lines can be suppressed from overlapping each other, and it is possible to realize a dot code to be positively read out.

1. In a dot code configured by a plurality of dots arranged in predetermined positions in a row direction and a column direction, a dot code characterized in that:
in rows on which the dots are arranged, which rows are adjacent to each other, arrangement is in a manner the dots deviate in phase.

2. A dot code according to claim 1, characterized in that the dots can be arranged on every other line and on every column.

3. A dot code according to claim 1, characterized in that the dots are arranged with a two-dot spacing in a row direction and a one-dot spacing in a column direction.

4. In a dot code printer for printing, to a medium, a dot code configured by a plurality of dots arranged in predetermined positions in a row direction and a column direction, a dot code printer characterized by comprising:
converting means for converting input data into a dot code; and
printing means for printing, to the medium, the dot code converted by the converting means;
the printing means arranging the dots in a manner the dots deviate in phase, in rows on which the dots are arranged, which rows are adjacent to each other.

5. A dot code printer according to claim 4, characterized in that the printing means can arrange the dots on every other line and on every column.

6. A dot code printer according to claim 4, characterized in that the printing means arranges the dots with a two-dot spacing in a row direction and a one-dot spacing in a column direction.

7. In a dot code printing method for a dot code printer to print, to a medium, a dot code configured by a plurality of dots arranged in predetermined positions in a row direction and a column direction, a dot code printing method characterized by comprising:
a converting step of converting input data into a dot code; and
a printing step of printing, to the medium, the dot code converted by the converting step;
in the printing step the dots are arranged in a manner the dots deviate in phase, in rows on which the dots are arranged, which rows are adjacent to each other.

8. In a dot code reader for reading out a dot code configured by a plurality of dots arranged in predetermined positions in a row direction and a column direction, a dot code reader characterized by comprising:
reading means for reading out the dot code configured by the dots in plurality;
binary means for making binary data read out by the reading means;
operating means for operating an exclusive OR on adjacent pixels in a column direction of data made binary by the binary means; and
determining means for determining a pause in a row of the dots on the basis of an operation result by the operating means.

9. A dot code reader according to claim 8, characterized in that the dots are arranged in a manner the dots deviate in phase, in rows on which the dots are arranged, which rows are adjacent to each other.

10. A dot code reader according to claim 8, characterized in that the dots the reading means is to read out can be arranged on every other line and on every column.

11. A dot code reader according to claim 8, characterized in that the dots the reading means is to read out are arranged with a two-dot spacing in a row direction and a one-dot spacing in a column direction.

12. In a dot code reading method of a dot code reader for reading out a dot code configured by a plurality of dots arranged in predetermined positions in a row direction and a column direction, a dot code reading method characterized by comprising:
a reading step of reading out the dot code configured by the dots in plurality;
a binary step of making binary data read out by the reading step;
an operating step of operating an exclusive OR on adjacent pixels in a column direction of data made binary by the binary step; and
a determining step of determining a pause in a row of the dots on the basis of an operation result by the operating step.
